(19) United States
(12) Patent Application Publication
(10) Pub. No.: US 2013/0008488 A1
(43) Pub. Date: Jan. 10, 2013

(54) USE OF ROTATING PHOTOVOLTAIC CELLS AND ASSEMBLIES FOR CONCENTRATED AND NON-CONCENTRATED SOLAR SYSTEMS

(76) Inventors: John W. HOLMES, Tainan City (TW); Chia-Chin Cheng, Tainan City (TW)

(21) Appl. No.: 13/542,056

(22) Filed: Jul. 5, 2012

Related U.S. Application Data
(60) Provisional application No. 61/505,154, filed on Jul. 7, 2011.

(51) Int. Cl. H01L 31/052; H01L 31/058

(52) U.S. Cl. 136/248; 136/246

(57) ABSTRACT

A concentrated and non-concentrated solar photovoltaic (PV) system with rotating PV cells or cell assemblies is provided to enhance cooling, receive both concentrated and non-concentrated sunlight, avoid hot spots and prolong PV cell operation life. The solar PV system comprises: one or more reflectors having a sun-facing side and a non-sun-facing side; and one or more rotating members with attaching PV cells or cell assemblies disposed at the sun-facing side of the reflector, herein the rotating members are able to rotate. The one or more rotating members with PV cells or cell assemblies are placed at predetermined positions at the sun-facing side of the reflector, and, during operation, the PV cells or cell assemblies has at least one light illuminated surface which is able to receive reflected light from different positions of the reflector, the direct solar radiation from the sun or the diffused solar radiation from the surroundings.

### CROSS-REFERENCE TO RELATED APPLICATION

This application claims the benefit of US. Provisional Application No. 61/505,154, filed on Jul. 7, 2011, in the US. Patent and Trademark Office the disclosure of which is incorporated herein by reference.

### BACKGROUND OF THE INVENTION

1. Field of the Invention

The present invention generally relates to a solar PV system with photovoltaic (PV) cells, in particular to a solar PV system that simultaneously collects concentrated and non-concentrated sunlight with one or more rotating PV cells or cell assemblies. The PV cells or cell assemblies may form a part of a combined solar PV and solar thermal energy system.

2. Description of the Related Art

Solar technology deals with the use of solar energy for a multitude of practical applications. PV cells or cell assemblies convert solar energy directly into electrical energy using the Photovoltaic effect which is well known in the art.

Typical solar PV cells or cell assemblies comprise one or more stationary PV cells or cell assemblies positioned on a surface. The PV cells or cell assemblies capture solar energy and convert the captured solar energy into electrical energy. Solar energy comprises packets of energy (photons). When photons strike PV cells or cell assemblies, the photons may be reflected or absorbed, or they may pass through the PV cells or cell assemblies. The PV cells or cell assemblies are made out of a semiconductor material. When a photon is absorbed by the PV cells or cell assemblies, electrons from the atoms of the semiconductor material are dislodged from their position. This flow of electrons generates electrical energy. Generally speaking, the energy output of PV cells or cell assemblies are a direct function of the number of protons absorbed by the PV cells or cell assemblies. The energy output from PV cells or cell assemblies can be increased by concentrating solar radiation onto the PV cells or cell assemblies, thus increasing the number of protons per unit time reaching and absorbed by the PV cells or cell assemblies. This can be accomplished, for example, by use of parabolic reflectors, Fresnel mirrors, or convex lenses or other light concentrating optical devices. Fresnel and convex lens reflectors are typically used with multi junction PV cells or cell assemblies which require high concentration ratios. Linear or point-focus parabolic reflectors can be used with inexpensive silicon-based crystalline type PV cells or cell assemblies with lower concentration ratios. Depending on the concentration ratios, the captured solar energy can cause excessive heating of PV cells or cell assemblies, resulting in reduced solar energy conversion efficiency by the PV cells or cell assemblies and shortened operation life of PV cells or cell assemblies.

Recently, concentrating reflectors with sun-tracking ability to concentrate solar energy and provide higher energy output have been used for solar PV electricity production. Some technologies also focus on combining PV and thermal energy production which provides heat and PV electricity simultaneously. Conventional concentrated solar PV technology often places stationary PV cells or cell assemblies at or near the focal point (or line) of the concentrating reflectors or lens facing the concentrated sunlight to absorb concentrated sunlight energy. However, although concentration of sunlight increases the output of PV cells or cell assemblies, it also heats up the PV cells or cell assemblies and affects their performance if the heat retained by the PV cells or cell assemblies cannot be dissipated efficiently. For typical multi-crystalline or mono-crystalline PV cells or cell assemblies, the efficiency of the cells goes down significantly when their temperature reaches 70° C. and above. Moreover, the life of conventional PV cells or cell assemblies is drastically shortened in long-term high-temperature operation. Generally speaking, within the common operating temperature of 10 to 70° C., the performance of PV cells or cell assemblies increases as the temperature decreases under the same sunlight radiation level. Therefore, lowering the PV cells or cell assemblies temperature is an important aspect in concentrated and non-concentrated solar PV systems. Moreover, in a concentrated system, hot spots or uneven exposure to the concentrated sunlight can occur due to shifting or misalignment of the PV cells or cell assemblies with respect to the focal point of the concentrating mirror or lens system. The hot spots or uneven exposure can affect the performance and the cell life of the solar PV system.

In the absence of forced convection cooling or other add-on cooling methods, conventional PV cells or cell assemblies dissipate heat by surface radiation and natural convection to the surroundings. Some PV installations, in particular those using concentrated solar energy, may also utilize heat sinks attached to the PV cells or cell assemblies to increase cooling. There is an unresolved need for an apparatus that cools the PV cells or cell assemblies by increasing the surface convection of PV cells and cell assemblies. There is also a need to increase the power density and improve the uniformity of solar irradiation on the surface of PV cells or cell assemblies. This is of particular concern in large scale PV installations or when reflectors are used to increase the energy output of PV cells or cell assemblies.

### SUMMARY OF THE INVENTION

The present invention uses rotation of PV cells or cell assemblies to increase power output of PV cells or cell assemblies used with sunlight concentrating devices such as parabolic reflectors and other sunlight concentrating device. The rotation of PV cells or cell assemblies evenly distributes concentrated sunlight radiation on the surface of PV cells or cell assemblies. The rotation can also minimize possible hot spots in PV cells or cell assemblies caused by the mirrors or reflectors used in concentrated systems. In addition, the rotation of PV cells or cell assemblies also provides enhanced cooling by increasing convection cooling of PV cells or cell assemblies leading to an increase in cell efficiency and prolonged cell life. Moreover, by periodically rotating in and out of the focal point or focal line in a concentrated system, the rotating PV cells or cell assemblies will cool at a more rapid rate. During the time the PV cells or cell assemblies are outside the focal point, they will continue to produce electrical power (at a reduced rate) from the non-concentrated solar radiation, including direct radiation from the sun and diffused radiation from the surroundings. By placing PV cells or cell assemblies on the entire surface of the rotating member, the effective surface area of PV cells or cell assemblies is increased, resulting in an increase in the overall electrical energy produced from a given installation size. In a solar PV system, depending on the design of the reflectors, PV cells or cell assemblies placed at different regions on the sun-facing side can be exposed to solar radiation of different concentration ratios resulting in exposure to different radiation intensities. For example, in a linear-focus PV (trough type) system, when PV cells or cell assemblies are placed near the focal line facing the reflectors, PV cells or cell assemblies are exposed to the strongest concentrated radiation (highest concentration ratio); when PV cells or cell assemblies are moved away from the focal line or turned at an angle from the concentrated sunlight, the radiation intensity is reduced; when PV cells or cell assemblies are completely rotated away from the concentrated sunlight and face the opening (aperture) of the reflectors, the PV cells or cell assemblies are not exposed to the concentrated sunlight but the incoming non-concentrated sunlight from the sun, as well as diffused sunlight from the surroundings.

The present invention relates to rotating PV cells or cell assemblies arranged around the perimeter of a rotating member and sequentially exposed to concentrated solar radiation followed by exposure to non-concentrated solar radiation among regions with different solar radiation of a solar reflector as a means to both decrease cell temperature and to increase the power output from a given PV cells or cell assemblies installation. During continuous or periodic back-and-forth rotation, PV cells or cell assemblies around the perimeter can be exposed to both concentrated and non-concentrated solar radiation in different regions of the PV cells or cell assemblies. Furthermore, the strength of radiation exposure of the rotating PV cells or cell assemblies in a concentrated solar PV system is determined by the concentration ability (called concentration ratio) of the concentrating reflector or lens system, as well as the placement of the PV cells or cell assemblies on the sun-facing side (determined by the distance from the focal point or focal line of the concentrating reflector and the distance to the reflector as described above). The present invention also discloses an approach and methodology for placement and adjustment of the rotating PV cells or cell assemblies to achieve various desired exposure levels when used with a concentrated solar thermal system.

The disclosed methodology and approaches can also be used in a low-concentration or non-concentrated solar system where the solar reflectors are used to reflect sunlight to desired regions of the PV cells or cell assemblies with little or no concentration function. The disclosed methodology and approaches can therefore be utilized with both concentrated and non-concentrated solar PV systems.

In addition to the increased surface convection cooling of PV cells or cell assemblies by rotation, to further increase cooling of the PV cells or cell assemblies, the present invention can combine other cooling methodologies or approaches. One approach disclosed by the present invention is to combine the rotating PV cells or cell assemblies with an internal flow system and utilize a heat transfer medium (solid, liquid or gas) to recycle thermal energy generated from the PV cells or cell assemblies. The heat recycling system of the current invention may also combine with a separate thermal energy collecting unit which utilizes the same solar concentrator (reflector) to simultaneously produce PV electricity and thermal energy at higher temperatures. Other heat dissipating methods such as heat sink, heat pipe, and forced convection are also disclosed with the present invention and are integrated with the components of the system.

Therefore, a primary objective of the present invention is to provide a solar PV system with rotating PV cells or cell assemblies, especially a concentrated solar PV system with rotating PV cells or cell assemblies which collect concentrated and non-concentrated sunlight of different radiation levels during continuous or periodic rotation.

To achieve the foregoing objectives, aspects of the present invention use rotation of PV cells or cell assemblies to make better use of space in solar PV systems, provide enhanced cooling of PV cells or cell assemblies, increased energy output, increased PV cell life, and reduced cost of solar energy. The disclosed methodology and approaches can be utilized with both concentrated and non-concentrated solar PV systems. The rotation can be at a constant speed, varying speed, periodic (start-and-stop) or bi-directional (back and forth) rotation. This allows adjusting the rotational speed or position of the PV cells or cell assemblies to optimize the energy output as well as the cooling characteristics for a variety of solar intensity levels and PV cells or cell assemblies' types.

However, aspects of the present invention are not restricted to the one set forth herein. The above and other aspects of the present invention will become more apparent to one of ordinary skill in the art to which the present invention pertains by referencing the detailed description of the present invention given below.

According to an aspect of the present invention, provided is a concentrated and non-concentrated solar PV system with rotating PV cells or cell assemblies, comprising: one or more reflectors having a sun-facing side and a non-sun-facing side; one or more PV cells or cell assemblies attached along the perimeter of one or more rotating members which could be hollow or solid and of arbitrary cross section and length.

Preferably, the PV cells or cell assemblies may be attached to all or a fraction of the rotating member's surface.

Preferably, the PV cells or cell assemblies are attached to the rotating member on standoffs which act as either heat insulators or as heat conductors, including the possibility of standoffs in the form of heat pipes to remove heat from the PV cells or cell assemblies.

Preferably, the rotating member with PV cells or cell assemblies can be placed at any location with respect to the focus (focal points, lines or planes) of the reflectors on the sun-facing side to receive desired solar intensity.

Preferably, multiple rotating members with PV cells or cell assemblies can be placed at different locations with respect to the focus (focal points, lines or planes) of the reflectors on the sun-facing side to receive desired solar intensity at various levels.

Preferably, the rotating member with PV cells and cell assemblies can be placed at any location with respect to the focal points of a lens system on the sun-facing side to receive desired solar intensity.

Preferably, the rotating members may further comprise an internal flow channel of arbitrary shape, cross section and length.

In the preferred embodiment of the present invention, the flow channel may be filled with a solid, liquid or gas.

Preferably, the rotating members could be used as a thermal energy collecting unit.

Preferably, the rotating members could be used as a heat sink to further cool the PV cells or cell assemblies.

Preferably, the rotating member is further coated with thermal absorption coating or thermal emissive coating on the outer or inner surface, or the outer and the inner surface.

Preferably, the one or more rotating members may have helix spiral shape with the possibility that the helix supporting structure serves as a heat sink, a heat pipe or as a flow channel for a fluid.

Preferably, the one or more rotating PV cell or cell assemblies may have a plurality of patterns including square, triangular, or circular shape or a combination thereof.

Preferably, the one or more rotating members has a cross section in the shape of hexagonal, octagonal, circular, elliptical, triangular, or rectangular shape or a combination thereof.

In another aspect of the present invention, the present invention may further comprise a slip ring attached to each of the one or more rotating members for the purpose of transmitting the electrical energy from the PV cells or cell assemblies.

Preferably, the one or more reflectors may have a flat, “U”, “V”, bent, waved, Fresnel, curved, parabolic or quasi-parabolic cross-sectional shape extended in a linear direction or point-focus dish, parabolic, curve, or Fresnel shape, as well as other suitable shapes. The reflectors may form one or more foci or focal regions to which the sunlight is concentrated, including focal point(s), focal line(s), focal plane(s) or focal area(s), depending on the geometry of the reflectors.

In another aspect of the present invention, the present invention may further comprise a plurality of connectors, the connectors each has one end connected to PV cells or cell assemblies and the other end to the rotating member(s).

Preferably, the plurality of connectors could be in the form of a heat sink or heat pipe.

Preferably, the concentrated and non-concentrated solar PV system with rotating PV cells or cell assemblies may further comprise one or more thermal energy collecting units to be placed with the one of more rotating members with attached PV cells or cell assemblies on the sun-facing side of the one or more reflectors. The thermal energy collecting unit may be a heat receiver tube or a heat engine.

Preferably, the sun-facing side of the reflector(s) may have a first focus and a second focus or plurality of foci.

Preferably, the first focus and the second focus or plurality of focus may have parallel axes, and the second focus or plurality of foci are closer to the reflector than the first focus is.

Preferably, the PV cells or cell assemblies may be disposed at or near the first focus or at or near a second focus.

Preferably, the PV cells or cell assemblies may be disposed at or near the first focus or at or near one or more separate foci.

Preferably, the system is comprised of a rotating PV cells or cell assemblies disposed at or near the first focus and another PV cells or cell assemblies or thermal energy collecting units located at or near one or more separate foci.

Preferably, the thermal energy collecting units may be disposed at or near the first focus.

The concentrated and non-concentrated solar PV systems with rotating PV cells or cell assemblies according to the present invention may have the following advantages:

(1) Increased cell cooling. The efficiency of PV cells typically decreases when operated at high temperatures. The increase in cooling rate obtained by rotating of the PV cells can reduce PV cell temperature, provide increased energy output and improve PV cell life. The cell cooling can be further increase by additional cooling approaches, including heat transfer to a solid, liquid or gas filled tube or chamber with the attached PV cells or PV cell assemblies.

(2) Even exposure to solar radiation over time. Rotation of the PV cells or cell assemblies reduces hot spots and provides even exposure to solar radiation of various strengths over time when used with optical reflectors. This improves the PV cell performance and life and reduces the need for maintenance. Moisture on the face of PV cells or cell assemblies will also be more effectively removed by the increased convection associated with rotation.

(3) Larger effective surface area of the PV cells or cell assemblies for enhanced power output when used with optical reflectors. Simultaneously, PV cells or cell assemblies on the sun-facing side of a rotating member, such as a heat receiver tube, receive non-concentrated solar energy, while those facing the optical reflectors receive concentrated solar energy. This increases the available power density from a fixed space and also allows for more compact PV systems and decreases the overall price per kW or output power from the PV cells or cell assemblies and also allows for residential applications where available space for installations is typically limited.

(4) During rotation, all cells produce power. The PV cells or cell assemblies that are in the focus region or reflected region and facing the optical reflectors will produce a higher output while the PV cells or cell assemblies outside the focus or reflected region will produce solar power from non-concentrated (including direct and diffused) sunlight while simultaneously radiating away a portion of the heat absorbed.

(5) During continuous rotation and even when rotation is periodically stopped, all cells continue to produce power. The PV cells or cell assemblies on the upper surfaces away from the focus of the optical reflector will continue to produce power under non-concentrated or diffused sunlight and direct sunlight while the PV cells or cell assemblies facing the reflector will operate under concentrated energy. The rotational speed and possible stopping duration can be continuously adjusted to optimize both cooling and energy production.

(6) The technology is general and can be used with all types of PV technology including poly-crystalline, mono-crystalline, multi junction and thin film PV approaches.

(7) Different PV cell types can be used along different portions of the rotating members; this allows, for example, selectively rotating PV cells or cell assemblies into focus to take advantage of PV cells or cell assemblies that react to different levels of solar intensity.

(8) The solar PV system with rotating PV cells or cell assemblies can include one or more rotating members located at different positions with respect to the focus (focal point or focal line) of the reflector to receive different levels of solar intensity depending on the PV cell types or electricity output requirements.

(9) The solar PV system with rotating PV cells or cell assemblies can be used in conjunction with a concentrated solar thermal system to share the same reflector or reflectors. This also makes it easy to retrofit an existing concentrated solar thermal system (for example a parabolic trough system or a dish system) with PV electric power generation capability.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1A illustrates concentrated and non-concentrated solar radiation of a cross sectional view of a rotating member with PV cells or cell assemblies attached to the surface and partially illuminated with a linear-focus parabolic or curved reflector;

FIG. 1B illustrates a schematic view of concentrated and non-concentrated (direct and diffused) solar energy radiating to a rotating PV cells or cell assemblies;

FIG. 2 illustrate a cross sectional view of a rotating member with PV cells or cell assemblies attached to the surface with various configurations of the reflector;

FIGS. 3A-3B illustrate cross sectional views of a rotating PV cells or cell assemblies with a Fresnel and a dish reflector;

FIG.4 illustrates a schematic view of use of a heat transfer liquid, air, or gas flow through flow channel;

FIG. 5 illustrates schematic views of various patterns for attaching PV cells or cell assemblies onto the rotating member;

FIG. 6 illustrates schematic views of various geometries of the rotating member;

FIGS. 7-10 illustrate schematic views of a rotating member covered partially with PV cells or cell assemblies;

FIG. 11 illustrates a schematic view for a slip ring system allowing electric power flow from a rotating PV cells or cell assemblies;

FIG. 12 illustrates a schematic view of the use of a rotating PV cells or cell assemblies with a solar power tower system;

FIGS. 13-14 are schematic views for convective cooling of rotating PV cells or cell assemblies;

FIG. 15 is a cross-sectional view of a parabolic reflector with adjustable placement of the rotating PV cells or cell assemblies;

FIG. 16 is a cross-sectional view of a parabolic reflector with multiple rotating PV cells or cell assemblies;

FIG. 17 is a cross-sectional view of a hybrid rotating PV-thermal system with a parabolic reflector with a thermal energy collecting unit placed at or near a focus and a rotating PV cells or cell assemblies placed at a distance from the focus.

FIG. 18 is a cross-sectional view of a dual-focus Fresnel reflector configuration with two rotating PV cells or cell assemblies.

FIG. 19 is a cross-sectional view for a dual-focus parabolic reflector with rotating PV cells or cell assemblies disposed at or near one focus (f1) and one thermal energy collecting unit disposed at or near a second focus (f2).

### DETAILED DESCRIPTION OF THE PREFERRED EMBODIMENTS

Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims.

In the drawings, sizes and relative sizes of layers and regions may be exaggerated for clarity.

Embodiments of the invention are described herein with reference to cross-section illustrations that are schematic illustrations of idealized embodiments of the invention. As such, variations from the shapes of the illustrations as a result, for example, of manufacturing techniques and/or tolerances, or of design variations of a similar function are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

The following are some definitions that may be helpful in understanding the description of the present invention. These are intended as general definitions and should in no way limit the scope of the present invention to those terms alone, but are put forth for a better understanding of the following description.

Unless the context requires otherwise or it is specifically stated to the contrary, integers, steps, or elements of the invention recited herein as singular integers, steps or elements clearly encompass both singular and plural forms of the recited integers, steps or elements. For example, as used herein, PV cells, PV cell assembly, PV cell assemblies and PV cell modules may include one or more PV cells or PV cell assemblies. In other words, the number of PV cells or cell assemblies is not limited in the present invention.

Throughout this specification, unless the context requires otherwise, the word “comprise”, or variations such as “comprises” or “comprising”, will be understood to imply the inclusion of a stated step or element or integer or group of steps or elements or integers, but not the exclusion of any other step or element or integer or group of elements or integers. Thus, in the context of this specification, the term “comprising” means “including principally, but not necessarily solely”.

Those skilled in the art will appreciate that the invention described herein is susceptible to variations and modifications other than those specifically described. It is to be understood that the invention includes all such variations and modifications.

Hereafter, exemplary embodiments of the present invention will be described in further detail with reference to the accompanying drawings.

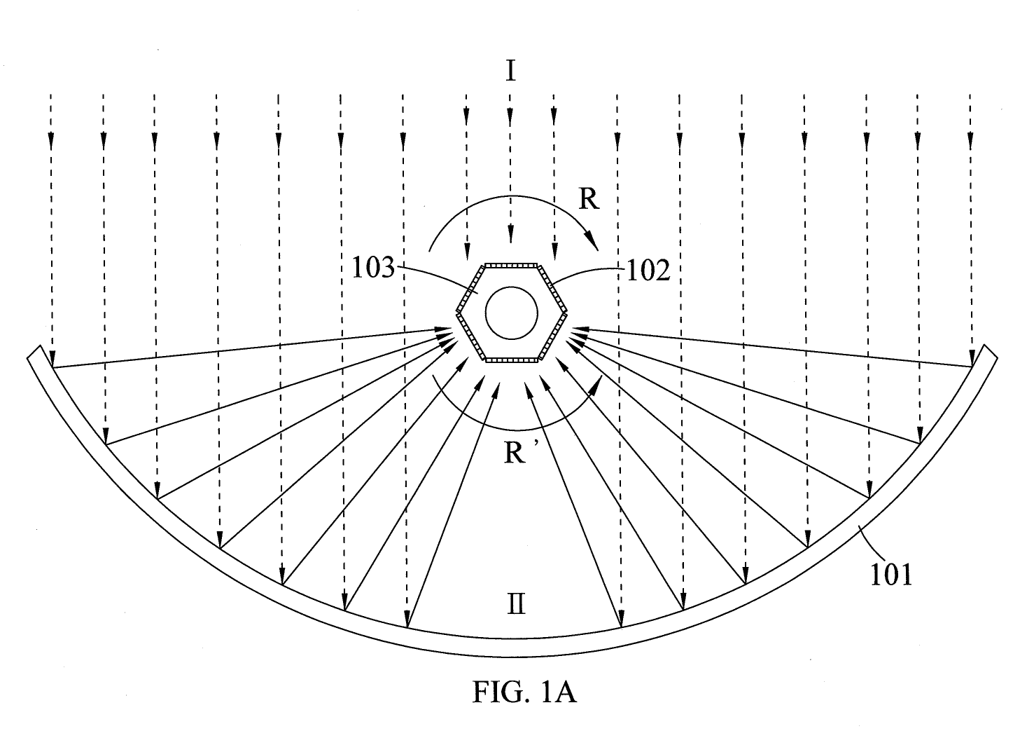

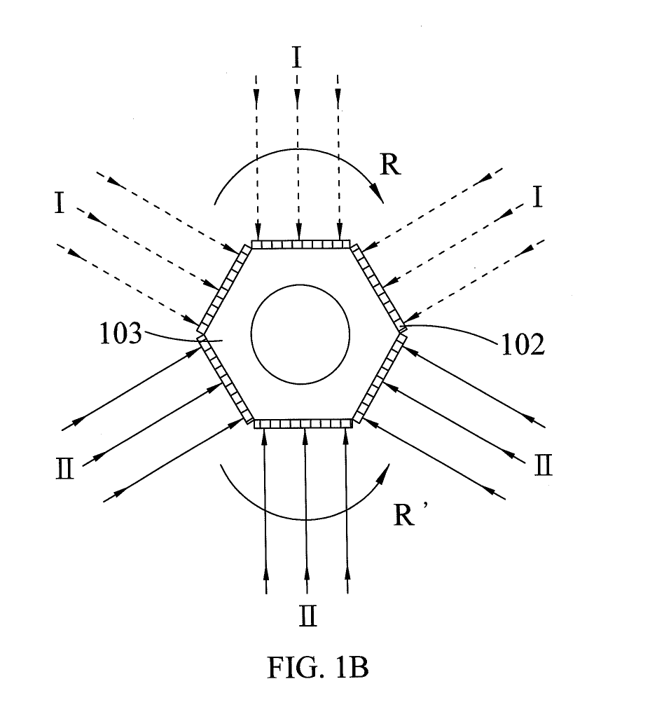

Referring to FIG. 1A, FIG. 1A illustrates a cross sectional view of a rotating member with PV cells or cell assemblies attached to the surface and partially illuminated by concentrated sunlight from a linear-focus parabolic or curved reflector and partially illuminated by non-concentrated sunlight. Said attached PV cells or cell assemblies 102 extending in the axial direction at or near the focal line of the reflector(s) 101. The concentrated (see solid line II in FIG. 1A) and non-concentrated (see dotted line I in FIG. 1A) solar PV system with rotating PV cells or cell assemblies 102 according to the exemplary embodiment of the present invention comprises one or more reflectors 101, and PV cells or cell assemblies 102 attached to and covering all or a portion of the surface of a solid or hollow rotating member 103 of arbitrary cross sectional shape and extending in the axial direction parallel to the focal line of the reflector(s) 101. Reflector(s) 101 having a sun-facing (reflective) side and a non-sun-facing side; the PV cells or cell assemblies 102 attached or integrally formed as part of a rotating member 103, with the PV cells or cell assemblies 102 being disposed on all or part of the rotating member 103, and extending in the axial direction of the reflector(s) 101 and the PV cells or cell assemblies 102 may rotate in the arrow R or R′ direction (clockwise or counterclockwise direction in FIG. 1). However, the present invention is not limited thereto; for example, the PV cells or cell assemblies 102 may rotate in a periodic back-and-forth or start-stop manner through a fixed or varying rotational angle. The PV cells or cell assemblies 102 and the rotating member 103 can also remain stationary, that is, non-rotating, with PV cells or cell assemblies 102 surrounding the rotating member 103 receiving non-concentrated (I) or concentrated (II) sunlight depending upon their position.

In addition, referring to FIG. 1A and FIG. 1B, FIG. 1B illustrates a schematic view of concentrated and non-concentrated (including direct and diffused) solar energy radiating to a rotating PV cells or cell assemblies. The PV cells or cell assemblies 102 and the rotating member 103 that they are attached to are located at a predetermined distance from the focal region of the reflector(s) 101, and the PV cells or cell assemblies 102 have at least one surface which is able to receive and absorb sunlight. Moreover, by rotating member 103, the attached PV cells or cell assemblies 102 can be sequentially illuminated by concentrated (see solid line II in FIG. 1B) or non-concentrated (see dotted line I in FIG. 1B) solar energy, maximizing the power density and power output available from a limited space while simultaneously providing increased surface cooling by the enhancement in convective cooling by rotation. The cooling effect is also enhanced by the temporary decrease in solar radiation level as the PV cells or cell assemblies 102 rotate from the concentrated solar radiation region to the non-concentrated solar radiation region outside the focal region. Rotating member 103 can also act as a heat sink for further cooling of the PV cells or cell assemblies 102. Alternatively, if hollow, rotating member 103 can be cooled by the passage of a fluid or gas to extract additional heat from attached PV cells or cell assemblies 102; for this purpose, the interior can be completely hollow or with an internal heat sink attached to the inner wall of rotating member 103. The rotating member 103 can be further coated with thermal emissive coating on the outer or inner surface, or inner and outer surface (not shown in the figure) to increase thermal dissipation. Rotating member 103 can also function as a sealed heat pipe heat to extract energy.

The PV cells or cell assemblies 102 can be rotated continuously at a specified rotational speed or in a periodic (start-and-stop) fashion. Alternatively, by use of a variable speed drive system, the PV cells or cell assemblies 102 can also be rotated at a variable speed to optimize the power output for different daily or seasonal solar intensities or to change the cooling rate of the PV cells or cell assemblies 102. The rotational speed can be constant over a given rotational cycle or can be varied with time in any suitable manner. Alternatively, the PV cells or cell assemblies 102 may be rotated with a back-and-forth rotational motion through an arbitrary angle to optimize power output or change cooling rates. If PV cells or cell assemblies 102 having different properties are disposed along the rotating member 103, the rotation of member 103 can be indexed to bring various types of PV cells or cell assemblies 102 into the sunlight concentrating region of the reflector(s) 101 to take advantage of possible differences in cell output characteristics or temperature limitations of the different cell types. This indexing might be useful for optimizing power generation under different time varying solar radiation conditions.

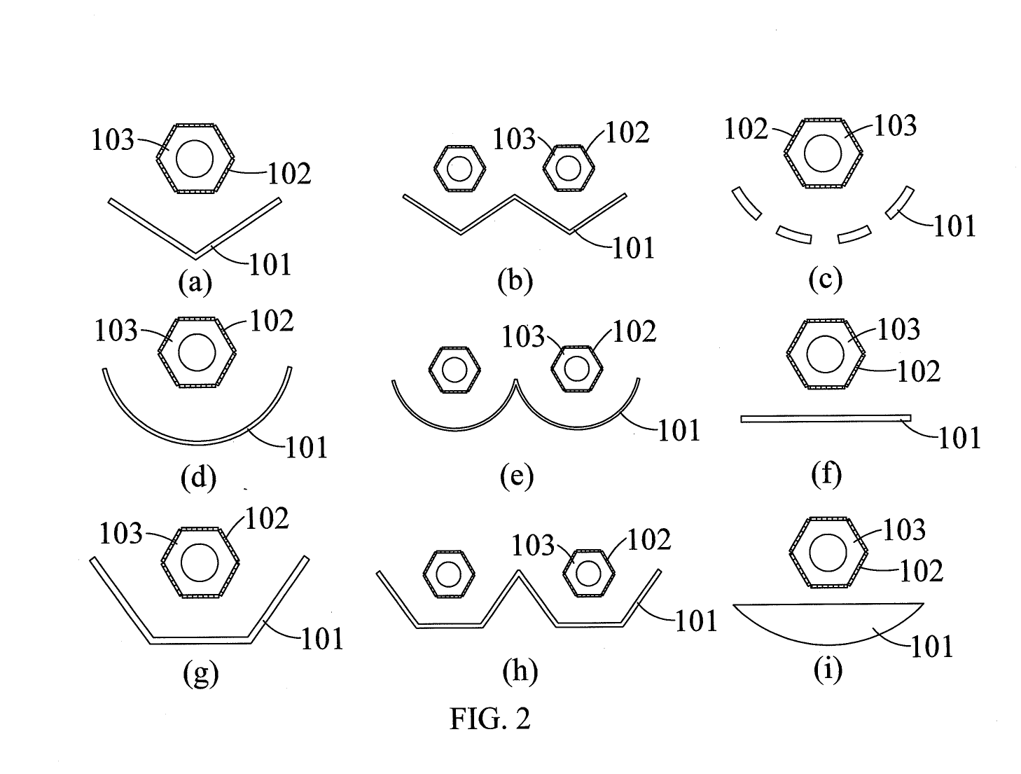

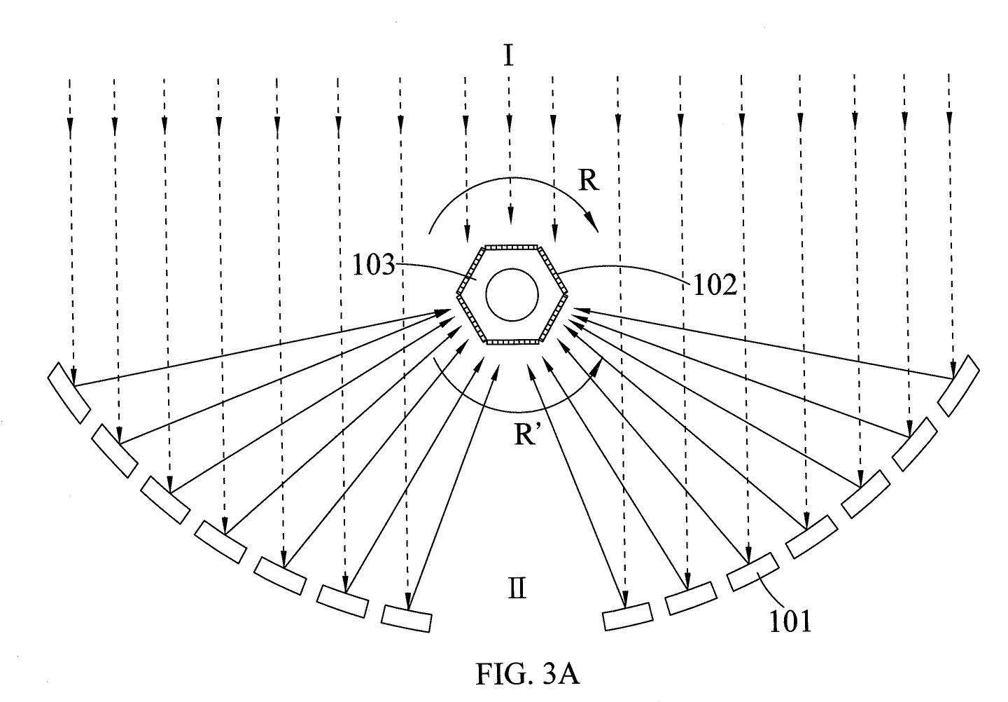

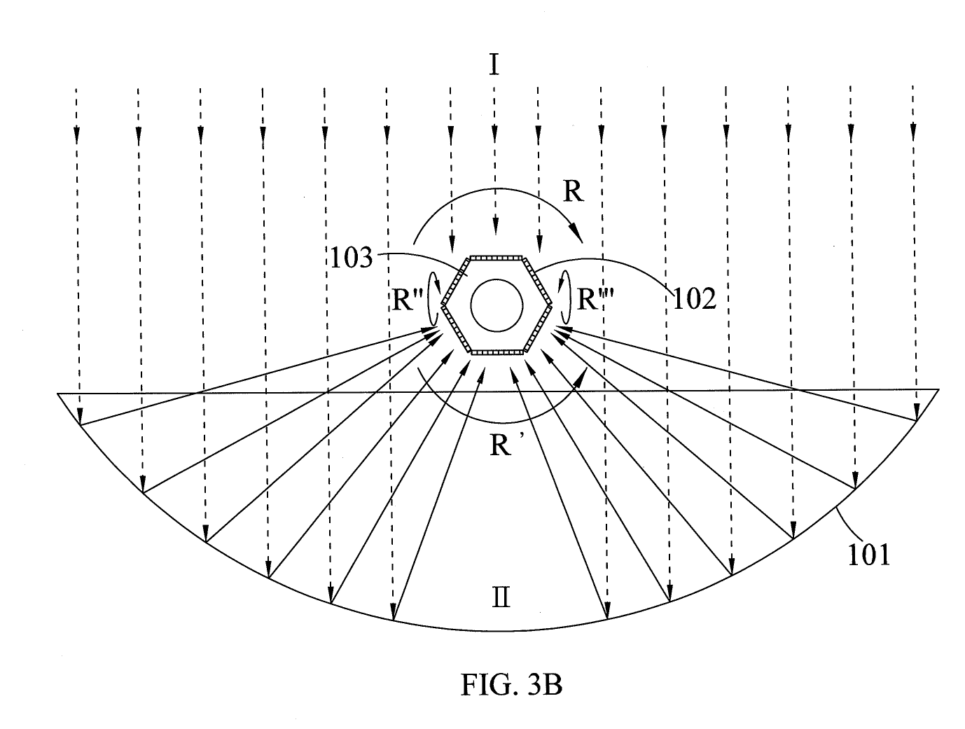

In addition, the type of the reflector(s) 101 is not limited thereto; referring to FIGS. 2-3, FIG. 2 illustrate a cross sectional view of a rotating member with PV cells or cell assemblies attached to the surface, with various configurations of the reflector. The reflector(s) 101 may have a flat, “U”, “V”, bent, waved, Fresnel, curved, parabolic or quasi-parabolic cross-sectional shape extended in a linear direction or a point-focus dish, parabolic or curved shape, as well as other suitable shapes, or a suitable combination thereof. The reflectors may form one or more foci or focal regions to which the sunlight is concentrated, including focal point(s), focal line(s), focal plane(s) or focal area(s), depending on the geometry of the reflectors (not shown in the Figure).

FIGS. 3A-3B illustrates cross sectional views of a rotating PV cells or cell assemblies with a linear-focus Fresnel and a dish reflector. The PV cells or cell assemblies 102 attached to rotating member 103 may receive solar energy from one or more suitably shaped reflectors 101, an exemplary embodiment of a Fresnel reflector is shown in FIG. 3A. Also, referring to FIG. 3B, the rotating PV cells or cell assemblies 102 can be coupled with a parabolic dish or semi-parabolic dish directing solar energy onto PV cells or cell assemblies 102, for this purpose said PV cells or cell assemblies 102 can be attached to rotating member 103 which has the shape of a sphere, cube, or other suitable geometry that can be rotated with respect to one or more axes, for example, in R, R′, R″ or R′″ directions shown in FIG. 3B. For simplicity, the following descriptions will illustrate possible differences; the elements substantially identical to those of the previous embodiment are indicated by like reference numerals and thus a detailed description thereof will be omitted or simplified.

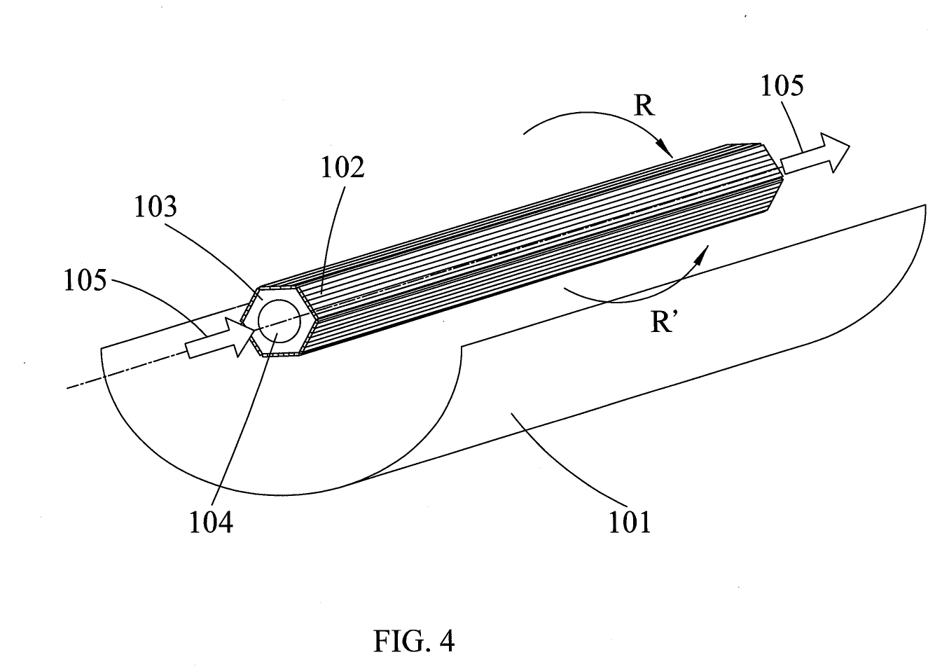

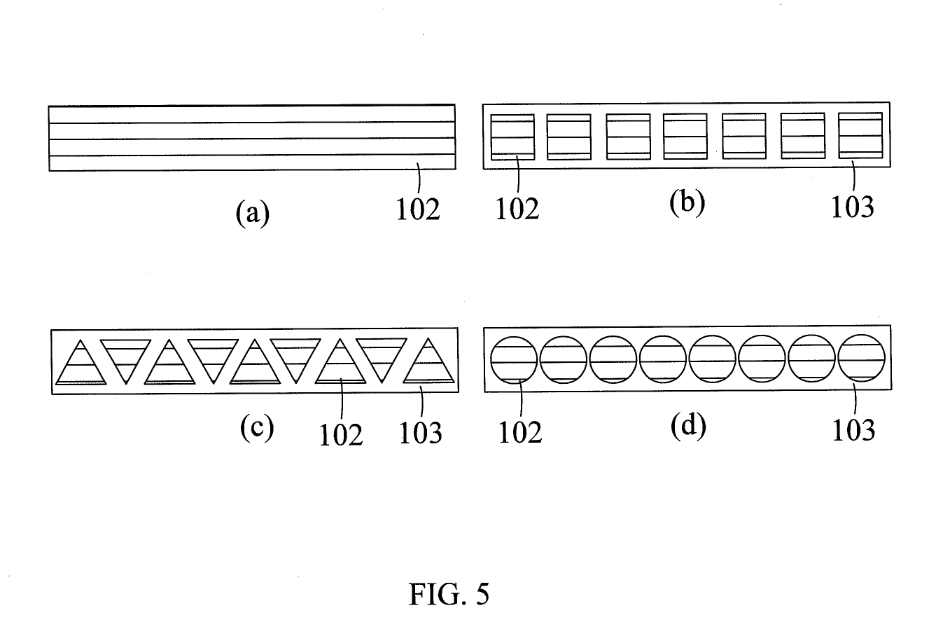

Referring to FIG. 4, FIG.4 illustrates a schematic view of use of a heat transfer liquid, air, or gas flow through a flow channel. A concentrated and non-concentrated solar PV system with rotating PV cells or cell assemblies 102 according to the present invention further comprises a flow channel 104, which can be an integral part of the rotating member 103. Moreover, the flow channel 104 can be filled with a heat transfer fluid 105. If rotating member 103 is used as a heat collecting member, the heat transfer fluid 105 within the flow channel 104 can be used to absorb heat energy to cool the PV cells or cell assemblies 102 thereby improving cell efficiency and also prolonging cell life. The absorbed thermal energy can be disposed of or used for another process requiring thermal energy. In another application, when the rotating member 103 is only partially covered with PV cells or cell assemblies 102 (such as shown in FIG. 5 and FIGS. 7-10), the heat transfer fluid 105 in the flow channel 104 can also absorb solar energy directly impinging onto one or more regions of the surface of rotating member 103 that are not covered by PV cells or cell assemblies 102. In a preferred embodiment of the said application, the one or more regions of the surface of rotating member 103 that are not covered by PV cells or cell assemblies 102 can be further coated with thermal absorption coating to increase absorption of thermal energy from the sunlight. In the said preferred embodiment, an insulating layer can be used between rotating member 103 and the PV cells or cell assemblies 102 to reduce thermal contact of PV cells and cell assemblies 102 with the rotating member 103. The solar thermal energy collected by the heat transfer fluid 105 (liquid, gas or solid) can be used for the purpose of providing thermal energy to a device or process.

Moreover, referring to FIG. 5. FIG. 5 illustrates schematic views of various patterns for attaching PV cells or cell assemblies onto the rotating member. FIG. 5 shows a variety of patterns for PV cells or cell assemblies 102 on one portion of the rotating member 103, said patterns can be square, triangular, circular, or other suitable shapes. Note that although only one side and one section is shown, PV cells and cell assemblies 102 can be fully or partially attached to other sides and other sections of the rotating member 103 in various configurations described above or in combination thereof.

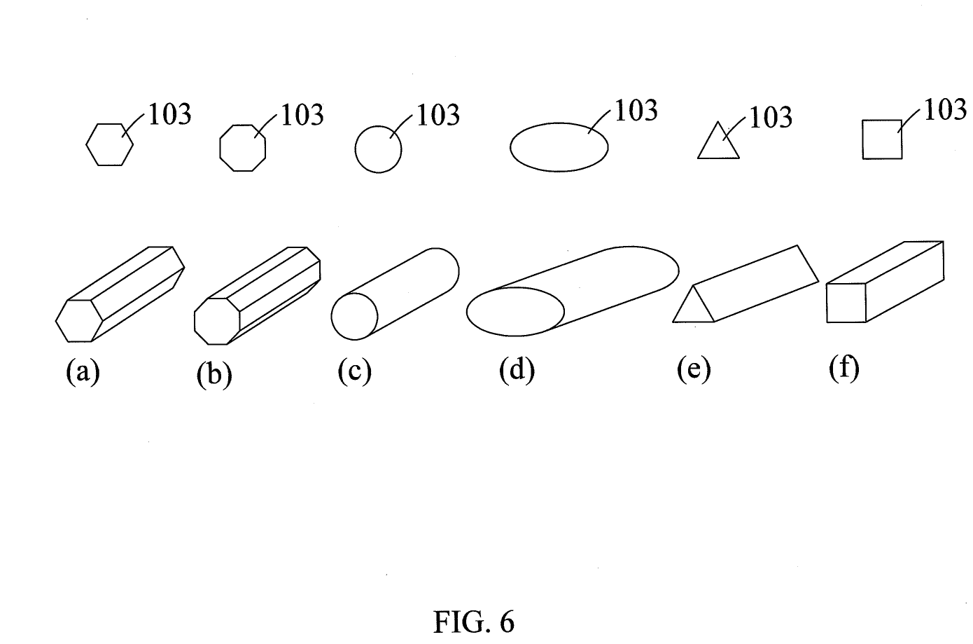

Moreover, referring to FIG. 6, FIG. 6 illustrates schematic views of various geometries of the rotating member. Some exemplary geometries of a section of the rotating member 103 are shown which have hexagonal, octagonal, circular, elliptical, triangular, rectangular, or other suitable shapes.

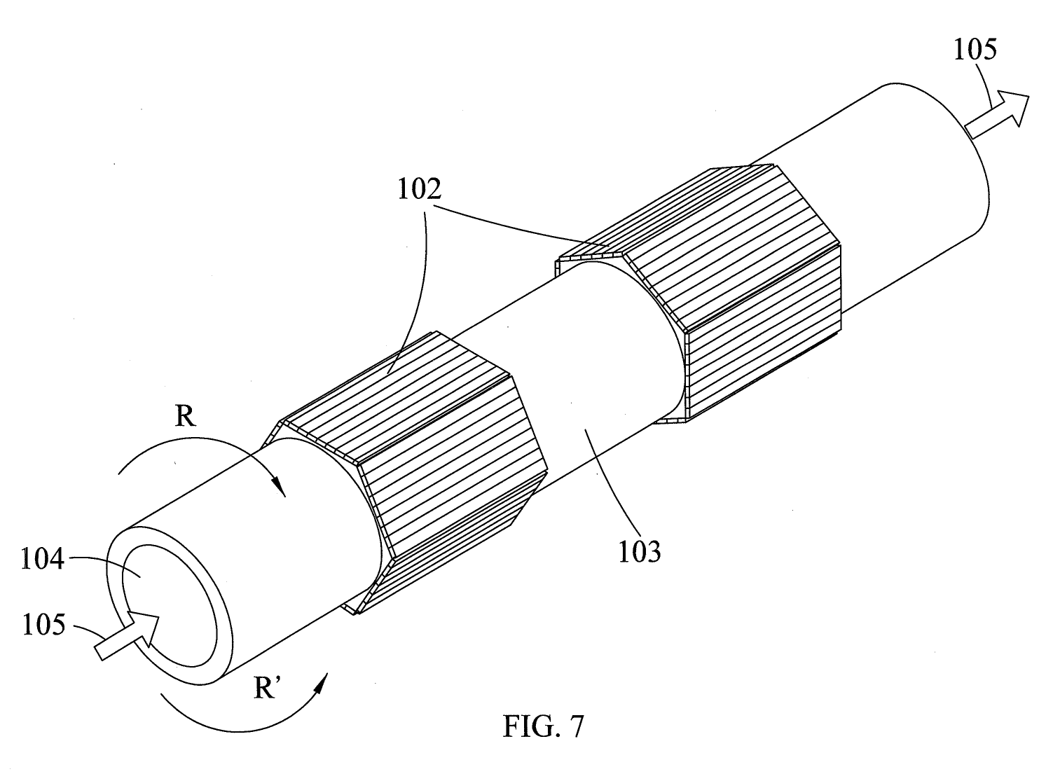

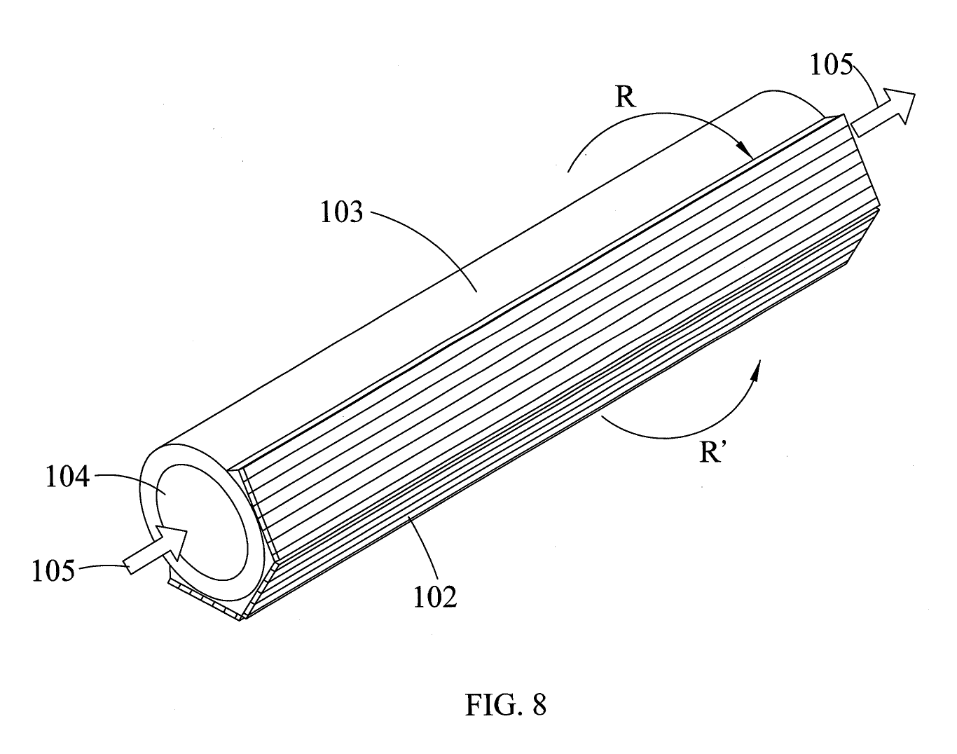

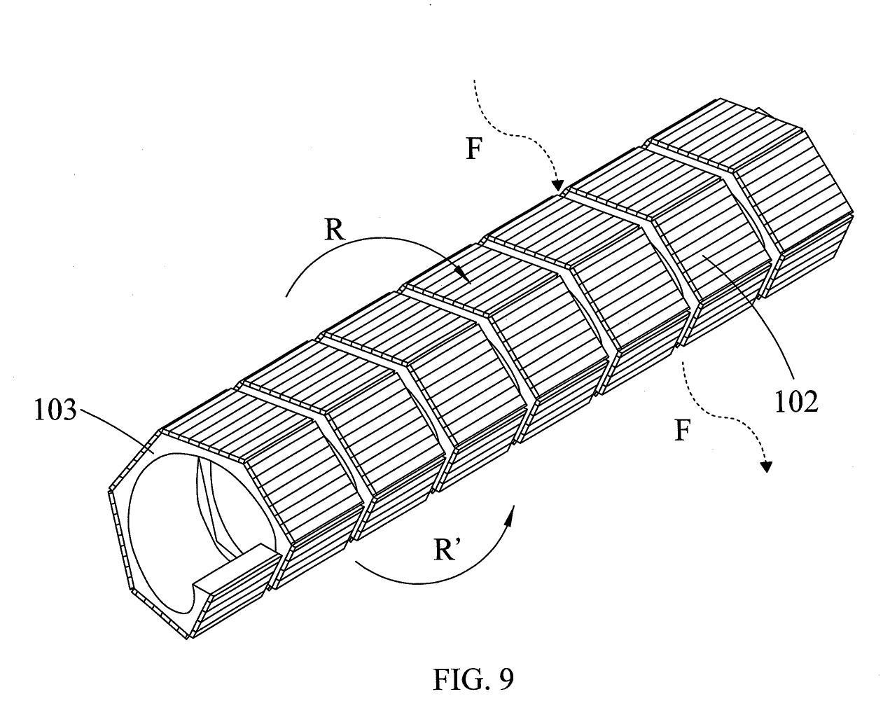

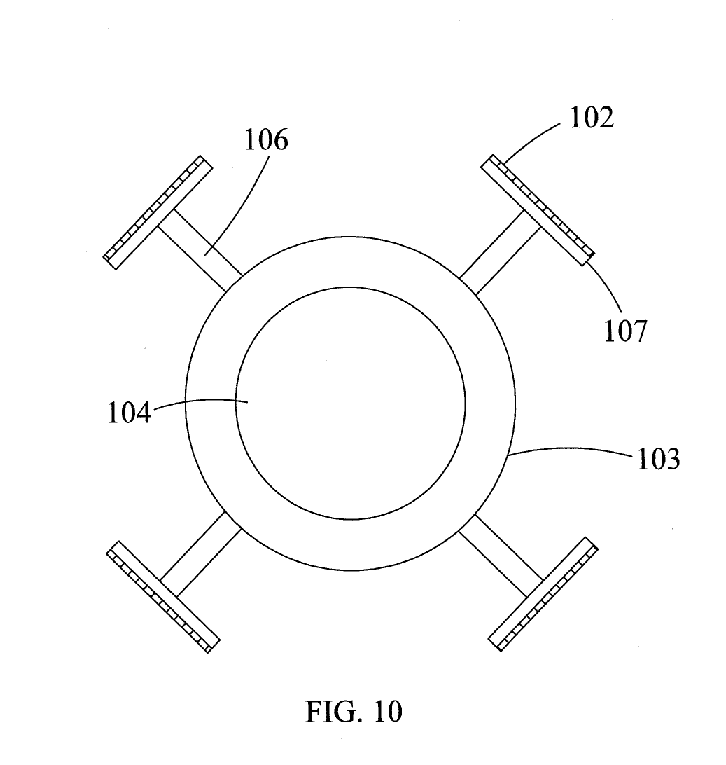

Referring to FIGS. 7-10, FIGS. 7-10 illustrate schematic views for use of partial coverage of a rotating member with attached PV cells or cell assemblies. In use, the PV cells or cell assemblies 102 and the rotating member 103 may rotate in a continuous, variable or start-and-stop manner. The rotating member 103 can be solid or contain a flow channel 104 which has a heat transfer fluid 105 within to collect heat from the attached PV cells and cell assemblies 102. The PV cells or cell assemblies 102 may fully or partially cover the outer surfaces of the rotating member 103 along a circumference or along its axial length, and may be rotated in the arrow R direction or R′ direction (see FIGS. 7-8) by a rotating device (not shown). On the other hand, the rotating member 103 may embodied as a helix spiral (see FIG. 9) supporting structure to support the PV cells or cell assemblies 102, which could also be a thermal energy collecting unit, and may be rotated in the R or R′ direction (see FIGS. 7-8) by the rotating member 103. In another embodiment, the PV cells or cell assemblies 102 can be attached to an open rotating form such as a stationary helix spiral or a slotted or perforated tube for the purpose of increased PV cells or cell assemblies 102 cooling by increasing air flow F through the spiral opening of the rotating member 103 such as shown in FIG. 9. However, these variations are not limited thereto. For example, if a closed structure is used, attachment of PV cells or cell assemblies 102 to a rotating member 103 that has a closed helix spiral shape can be used for the purpose of simultaneously cooling the PV cells or cell assemblies 102 and providing thermal energy to a heat transfer fluid 105. Referring to FIG. 10, a solar PV system with rotating PV cells or cell assemblies 102 according to the present invention further comprises a plurality of connectors 106 which can be hollow or solid or form a part or all of heat sink or heat pipe if desired, one end of said connectors 106 is attached to a rotating member 103 and a plurality of mounting surfaces or heat sinks 107 which are attached to another end of the plurality of connectors 106 respectively. Moreover, the PV cells or cell assemblies 102 are attached to the plurality of heat sinks 107 and the connectors 106. The plurality of heat sinks 107 are used to facilitate heat removal from the PV cells or cell assemblies 102 coupled to the reflector(s) 101 or other suitable system for focusing solar energy. The rotating member 103 can be of solid or hollow cross section. If hollow, an internal or flowing fluid can be used to extract heat from the attached PV cells or cell assemblies 102 connectors 106 attached to rotating member 103.

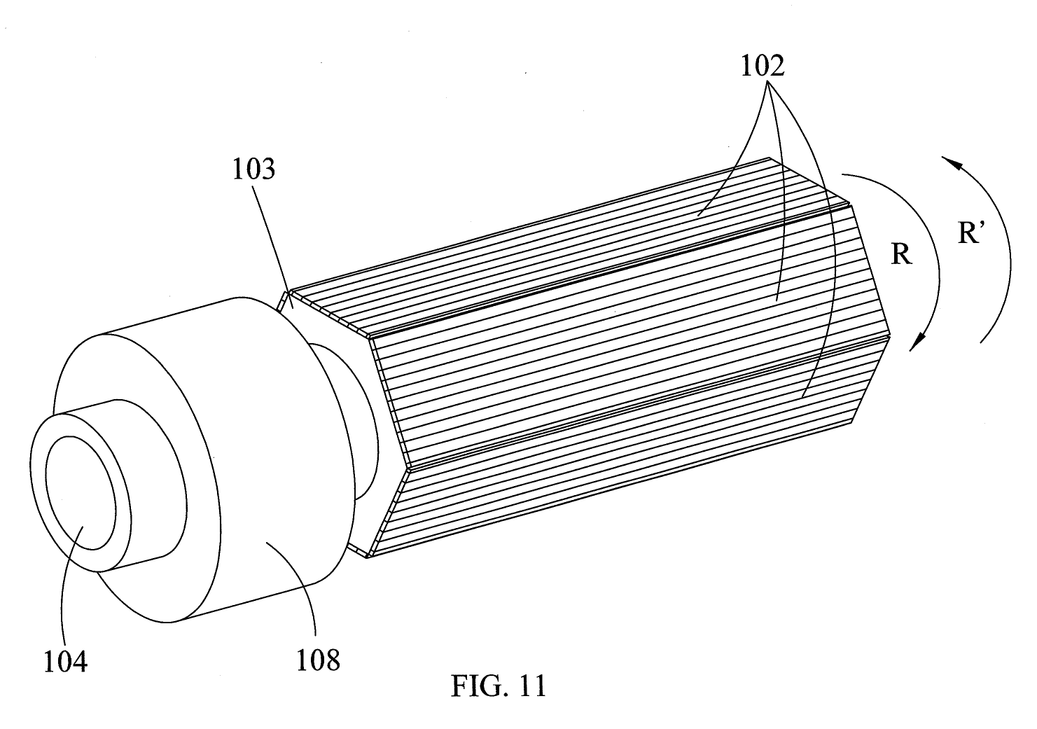

Referring to FIG. 11, FIG. 11 illustrates a schematic view for a slip ring system allowing electric power flow from a rotating PV cells or cell assemblies. The solar PV systems with rotating PV cells or cell assemblies 102 according to the present invention may further comprise a slip ring 108 attached to the rotating member 103. The slip ring 108 is used in conjunction with the PV cells or cell assemblies 102 as means to transfer electric power generated from the PV cells or cell assemblies 102 to a suitable stationary electrical connection.

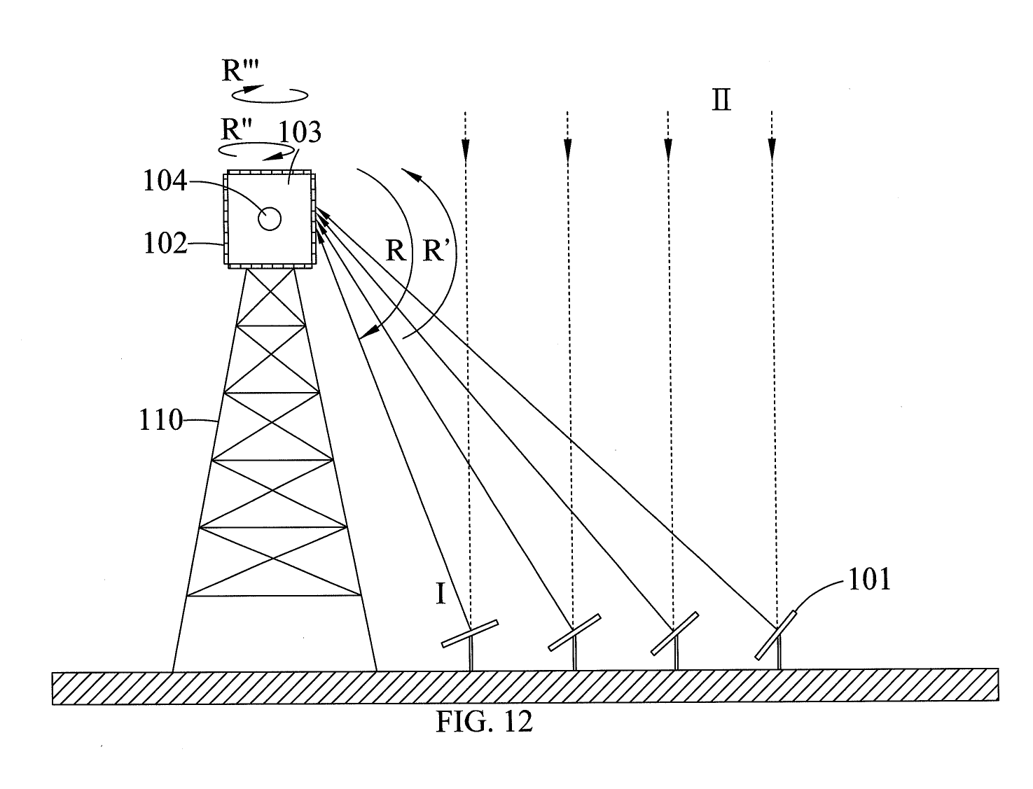

In another preferred embodiment, the rotation of PV cells or cell assemblies 102 may be used with power towers. Referring to FIG. 12, FIG. 12 illustrates a schematic view of the use of a rotating PV cells or cell assemblies with a solar power tower system. For application, the PV cells or cell assemblies 102 are attached to all or a portion of a rotating member 103 which rotates about one or more axes for example, in R, R′, R″ or R′″ directions and is used with power towers 110 where the reflector(s) 101 focus solar energy onto the rotating PV cells or cell assemblies 102. The rotating member 103 can be of any geometric shape and of solid or hollow construction; if hollow, a fluid can be used to enhance heat transfer from the PV cells or cell assemblies 102.

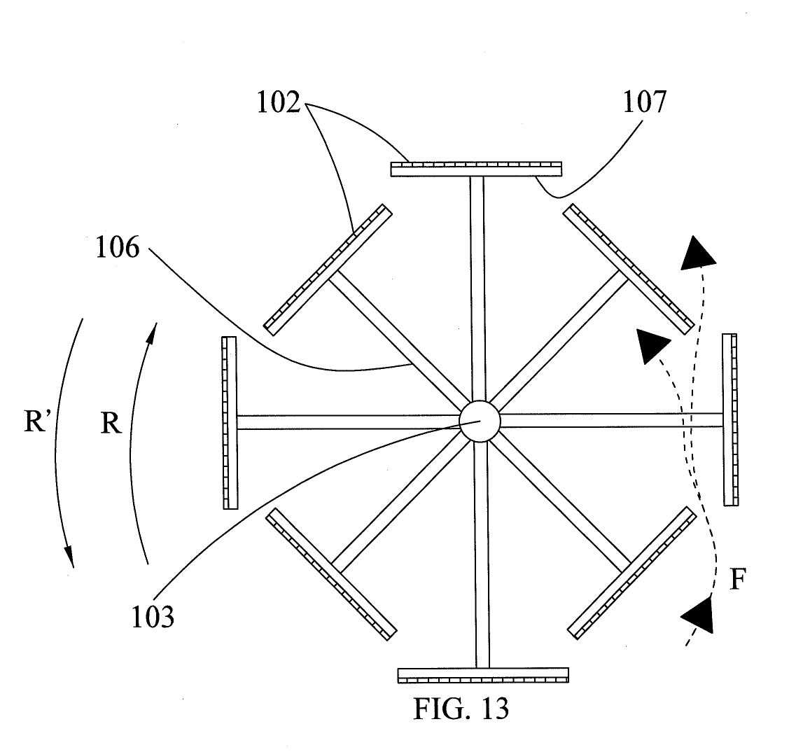

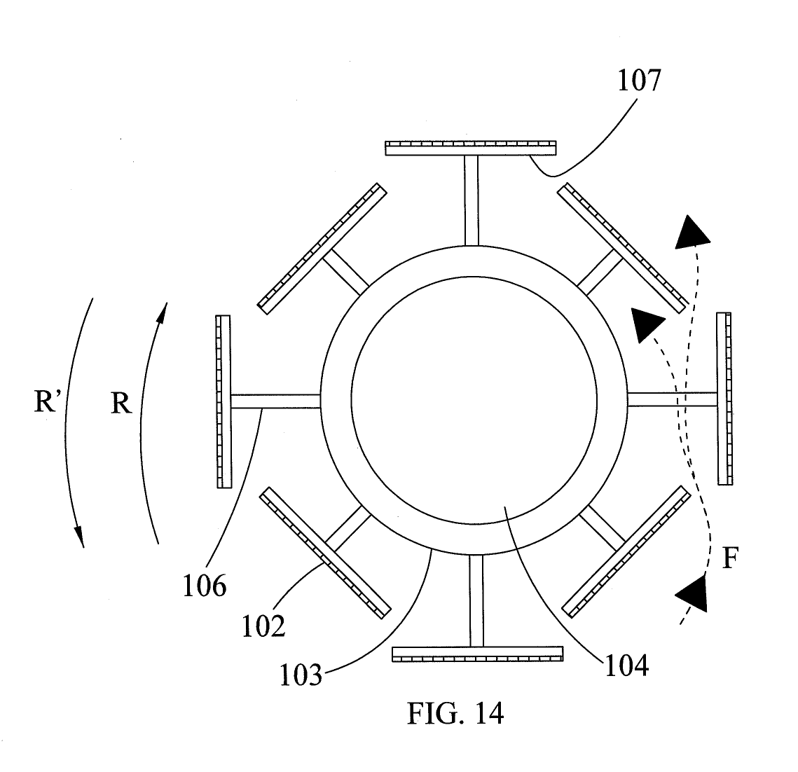

Referring to FIGS. 13-14, FIGS. 13-14 are cross-sectional views for convective cooling of rotating PV cells and cell assemblies. In another aspect of the present invention, the present invention may further comprise a plurality of connectors 106 which can also form a part of a heat sink 107 or a heat pipe, the connectors 106 each has one end connected to the rotating member 103 and another end connected to the PV cells or cell assemblies 102 with said PV cells or cell assemblies 102 extending in the axial direction along the rotating member 103. When the PV cells or cell assemblies 102 rotates in a direction R or R′, air flow F may flow and circulate around the rotating attached PV cells or cell assemblies 102 and also around the connectors 106 attached to the rotating member 103. The air flow F will cause a reduction in the PV cells or cell assemblies 102 temperature by convection cooling of the PV cells or cell assemblies 102, the connectors 106 and the rotating member 103. The rotating member 103 can be of solid or hollow cross section and of arbitrary cross section; if hollow (shown in FIG. 14), the channel can be used as a flow channel 104 for the purpose of providing cooling for the attached PV cells or cell assemblies 102. To provide additional cooling, a heat transfer fluid 105 can be used.

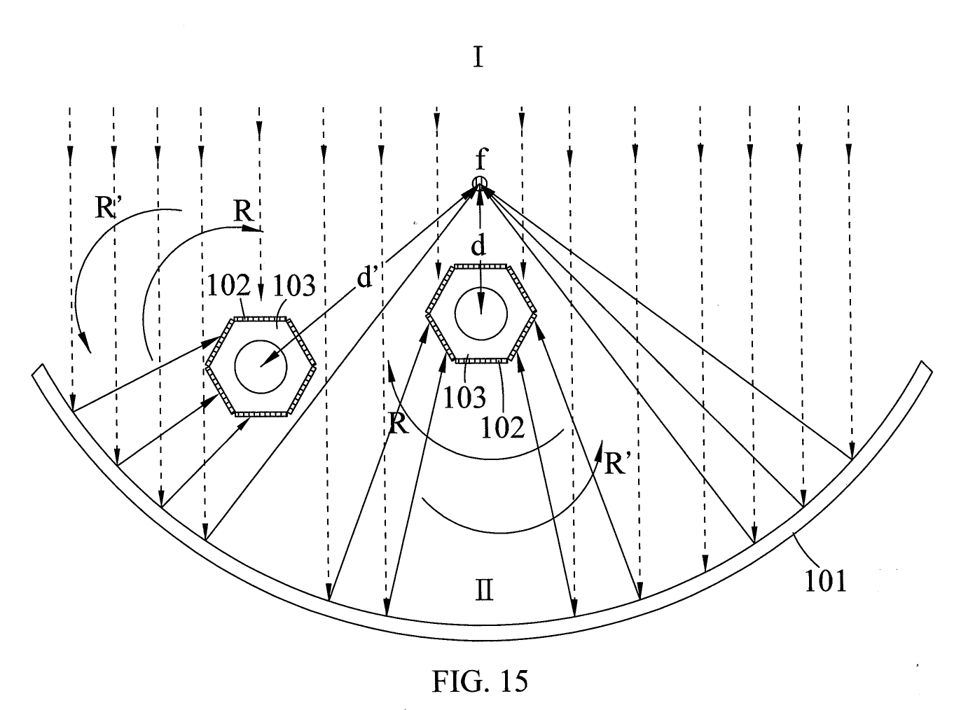

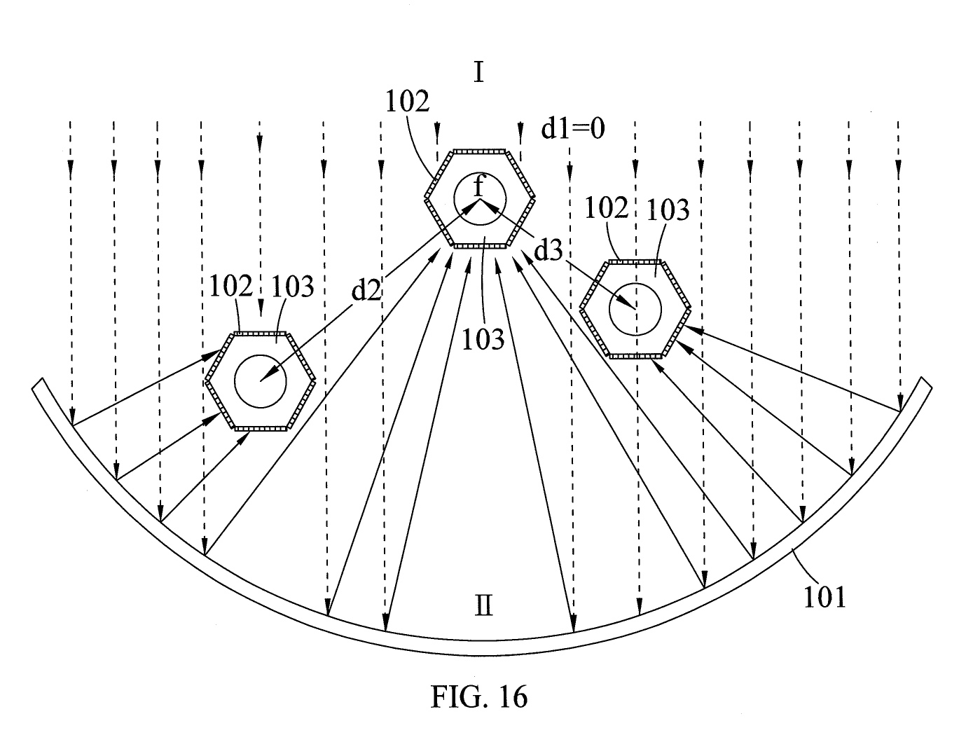

In another aspect of the present invention, depending on the requirements for solar intensity, the types of PV cells or cell assemblies 102 that are used and the optimal operating temperature of PV cells or cell assemblies 102, the rotating member 103 with PV cells or cell assemblies 102 may be placed at a distance from the primary focal line or focal point of the reflector(s) 101 on the sun-facing side to receive different levels of solar radiation. Furthermore, multiple rotating members 103 with PV cells or cell assemblies 102 of different requirements for solar intensity, temperature or different PV cells or cell assemblies 102 types can be attached at different positions along the surface of rotating member 103 located on the sun-facing side the reflector(s) 101. FIGS. 15-16 show two different embodiments that utilize 20 I this concept. Referring to FIG. 15, FIG. 15 is a cross-sectional view of a linear-focus parabolic reflector with adjustable placement of the rotating PV cells or cell assemblies. The solar PV system with rotating PV cells or cell assemblies 102 according to the present invention may have the rotating member 103 with PV cells or cell assemblies 102 placed at a distance d from the focal line or focal point (in cross-sectional view) of the reflector(s) 101.

Referring to FIG. 15, when the rotating member 103 with PV cells or cell assemblies 102 is placed at a shorter distance d from the focal line or focal point (in cross-sectional view) of the reflector(s) 101, the PV cells or cell assemblies 102 receives stronger solar radiation because radiation reflected from a larger portion of the reflector(s) 101 reaching the rotating member 103 with PV cells or cell assemblies 102. When the rotating member 103 with PV cells or cell assemblies 102 is placed at a longer distance d′ from the focal line or focal point of the reflector(s) 101, the PV cells or cell assemblies 102 receives weaker solar radiation, compared to placing at the distance d location, because radiation reflected from a smaller portion of the reflector(s) 101 reaching the rotating member 103 with PV cells or cell assemblies 102. The rotating member 103 with PV cells or cell assemblies 102 can be placed at an arbitrary location on the sun-facing side of the reflector(s) 101 to receive desired radiation strength. Furthermore, the present invention may further comprise an adjustment mechanism (not shown in the Figure) to adjust the distance d from the focal line or focal point of the reflector(s) 101 to change the exposure condition of the PV cells or cell assemblies 102.

In another aspect of the present invention, FIG. 16 is a cross-sectional view of a linear-focus parabolic reflector with multiple rotating PV cells or cell assemblies. Three rotating members 103 with PV cells or cell assemblies 102 are placed at predetermined or adjustable distances (d1, d2, d3 respectively) from the focal line or focal point (in cross-sectional view) of the reflector(s) 101. In the exemplary configuration, d1 is 0 as shown in FIG. 16 which indicates that the first rotating member 103 is placed at the focus of the reflector(s) 101. Note that the number of rotating members 103 with PV cells or cell assemblies 102 and the location of their placements are not limited to what has been illustrated in FIG. 16, which depends on the requirements of the system.

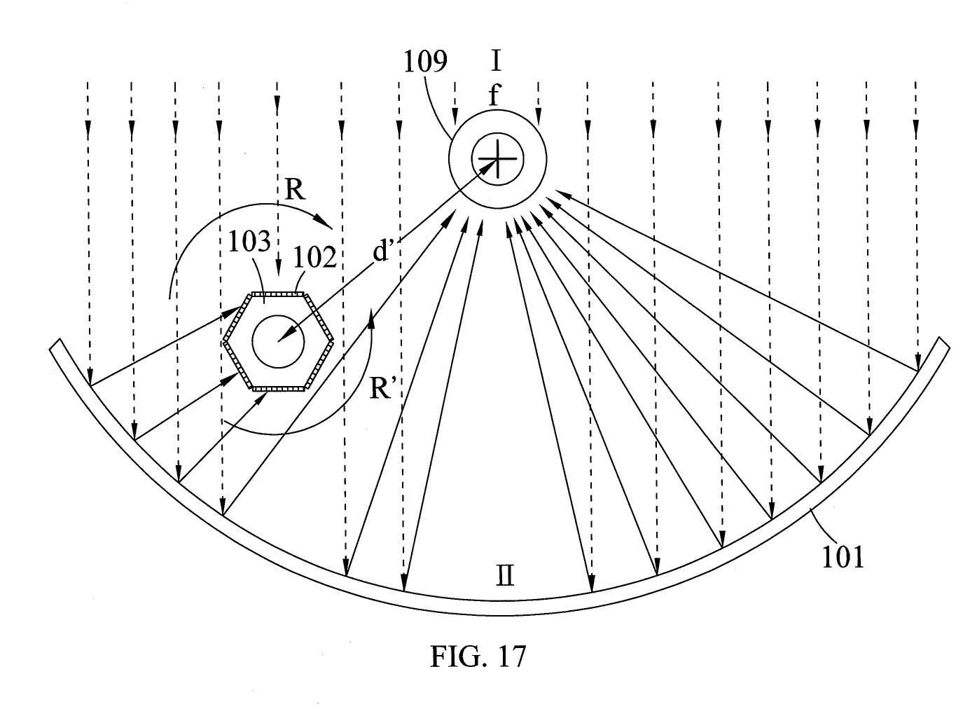

Referring to FIG. 17, FIG. 17 is a cross-sectional view of a hybrid rotating PV-thermal system with a linear-focus parabolic reflector with a thermal energy collecting unit placed at or near the focus and a rotating PV cells or cell assemblies placed at a distance from the focus. The solar PV systems with rotating PV cells or cell assemblies 102 according to the present invention may further comprise a solar thermal energy collecting unit 109, which can be a heat receiver tube, placing at or near the focal line or a focal point (in cross-sectional view) of the reflector(s) 101. One or more rotating members 103 with PV cells or cell assemblies 102 are placed at a distance d′ from the solar thermal energy collecting unit 109 on the sun-facing side of the reflector(s) 101. In this configuration, the rotating member 103 can be placed at any location above the reflector(s) 101 surface. This configuration can increase the energy conversion efficiency by collecting thermal energy and PV electrical energy at the same time and reduce the cost of a PV-thermal hybrid system using the same reflector(s) 101.

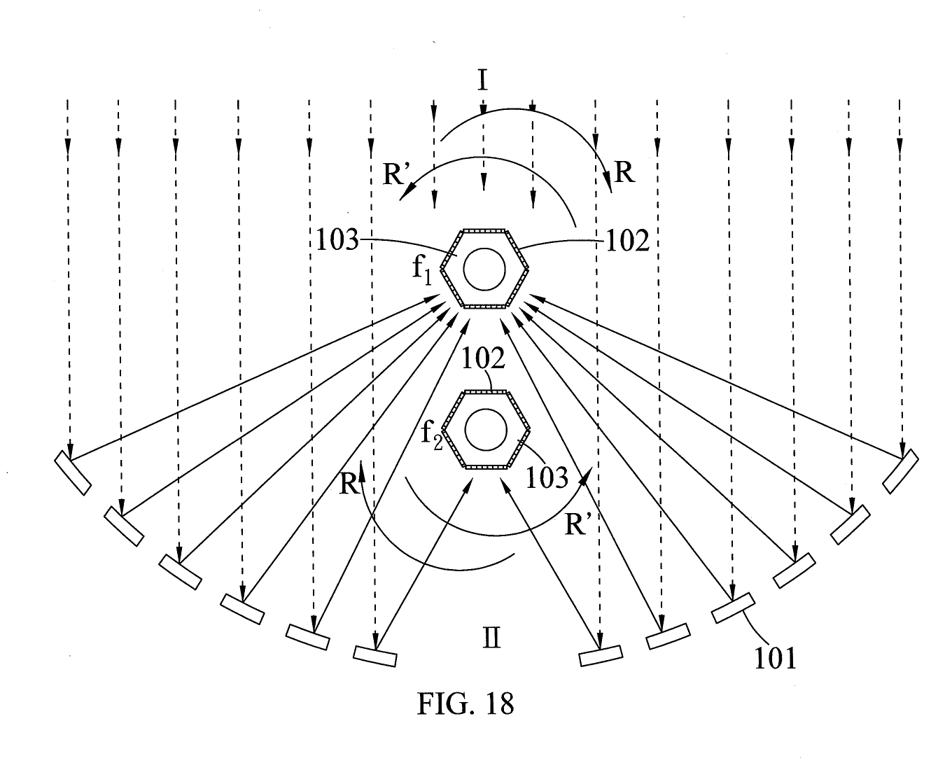

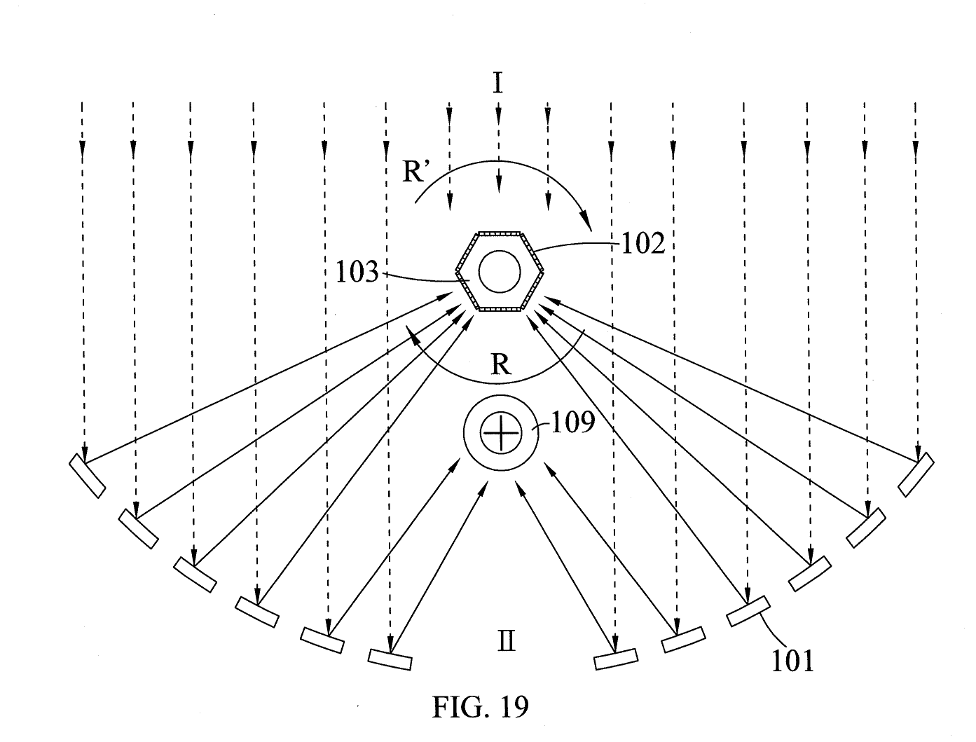

Referring to FIGS. 18-19, FIGS. 18-19 are cross-sectional views for a dual-focus linear Fresnel reflector and linear-focus parabolic reflector of rotating PV cells and cell assemblies. The concentrated and non-concentrated solar PV systems with rotating PV cells or cell assemblies 102 according to the present invention may further comprise a first focal line, shown as first focal point f1 in the cross-sectional view, and a second focal line, shown as second focal point f2 in the cross-sectional view, located on the sun-facing side of the reflector(s) 101. The first focal line, shown as first focal point f1 in the cross-sectional view, and the second focal line, shown as second focal point f2 in the cross-sectional view, have parallel axes, and the second focal line, shown as a second focal point f2 in the cross-sectional view, is closer to the reflector(s) 101. This configuration may produce more energy and allow more flexible combinations of solar PV and solar thermal energy produced using a given reflector system. The reflector(s) 101 may focus sunlight onto the rotating member 103 with PV cells or cell assemblies 102, at this time, the thermal energy collecting unit 109 may be a heat receiver tube; the PV cells or cell assemblies 102 located at a different focal line (separate from the thermal energy collecting unit 109) and receiving solar energy from the Fresnel reflector(s) 101 with a different focal distance.

While the means of specific embodiments in the present invention has been described by reference drawings, numerous modifications and variations could be made thereto by those skilled in the art without departing from the scope and spirit of the invention set forth in the claims. The modifications and variations should in a range limited by the specification of the present invention.

What is claimed is:

1. A concentrated and non-concentrated solar PV system with rotating PV cells and cell assemblies, comprising:
one or more reflectors, having a sun-facing side and a non-sun-facing side;
disposed at the sun-facing side of the one or more reflectors, one or more PV cells or cell assemblies attached to the outer perimeter and cover all or a portion of one or more rotating members; and wherein the one or more rotating members and the PV cells or cell assemblies have at least one surface irradiated by the sunlight reflected by the one or more reflectors or by the direct radiation from the sunlight and diffused radiation from the surroundings.

2. The solar PV system of claim 1, wherein the one or more rotating members are connected to a driving system and are able to rotate at specified speeds, motions, and directions.

3. The solar PV system of claim 2, wherein the rotation motions and speeds of the one or more rotating members are indexed and controllable to optimize the power output or to change the cooling rates of the PV cells or cell assemblies, including continuous rotation in a predetermined speed, start-and-stop mode, stationary, variable speed, or other predetermined rotational modes and speeds.

4. The solar PV system of claim 1, wherein the one or more rotating members are solid or hollow.

5. The solar PV system of claim 4, wherein the one or more rotating members are used as a heat sink.

6. The solar PV system of claim 1, wherein the one or more rotating members are hollow and is used as a open or closed flow channel for the purpose of providing cooling to the PV cells or cell assemblies attached to the outer surface.

7. The solar PV system of claim 1, wherein the one or more rotating members are hollow and is used as a open or closed flow channel to extract heat from the attached PV cells or cell assemblies or from regions of the one or more rotating members not covered with the PV cells or cell assemblies.

8. The solar PV system of claim 7, wherein the flow channel is further filled with gas, liquid or solids to take away heat generated from the PV cells or cell assemblies or to transfer heat from exposure to sunlight radiation.

9. The solar PV system of claim 6, wherein the one or more rotating members are further coated with thermal emissive coating on the outer or inner surface, or the inner and outer surfaces.

10. The solar PV system of claim 7, wherein the one or more rotating members are further coated with thermal absorption coating or thermal emissive coating on the outer or inner surface, or the inner and outer surfaces.

11. The solar PV system of claim 1, wherein the outer surface of the one or more rotating members are fully or partially covered with the PV cells or cell assemblies.

12. The solar PV system of claim 1, wherein the attachment of the PV cells or cell assemblies on the outer surface of the one or more rotating members have a plurality of patterns, including square, triangular, circular, other suitable shapes, or a combination therein.

13. The solar PV system of claim 1, wherein the one or more rotating members have a cross-section in the shape of hexagonal, octagonal, circular, elliptical, triangular, or rectangular shape, or a combination therein.

14. The solar PV system of claim 1, wherein the PV cells or cell assemblies are mono-crystalline, poly-crystalline, multi-junction, thin film, other PV cell types, or a combination thereof.

15. The solar PV system of claim 1, wherein the one or more rotating members have a helix spiral shape.

16. The solar PV system of claim 1, further comprising a slip ring disposed internally or externally to each of the one or more rotating members to transfer electricity to a stationary electrical connection.

17. The solar PV system of claim 1, wherein the one or more reflectors have a flat, “U”, “V”, bent, waved, Fresnel, curved, parabolic or quasi-parabolic cross-sectional shape extended in a linear direction or a point-focus dish, parabolic or curved shape, as well as other suitable shapes, or a combination therein.

18. The solar PV system of claim 17, wherein the one or more reflectors further have one or more foci or focal regions to which the sunlight is concentrated, including focal point(s), focal line(s), focal plane(s) or focal area(s), depending on the shape of the one or more reflectors.

19. The solar PV system of claim 1, wherein the one or more rotating members further comprising a plurality of connectors which has one end connected to the rotating member and the other end connected to the PV cells or cell assemblies.

20. The solar PV system of claim 19, further comprising a plurality of heat sinks disposed between the plurality of connectors and the PV cells or cell assemblies.

21. The solar PV system of claim 19, wherein the plurality of connectors are heat insulators or heat conductors.

22. The solar PV system of claim 19, wherein the plurality of connectors are heat pipes.

23. The solar PV system of claim 1, wherein the one or more rotating members are disposed at an arbitrary position on the sun-facing side of the one or more reflectors, including at or near one or more focal lines or focal points.

24. The solar PV system of claim 23, wherein the positions of the one or more rotating members are fixed or adjustable.

25. The solar PV system of claim 1, further comprising one or more thermal energy collecting units which are heat engines or heat receiver tubes.

26. The solar PV system of claim 1, wherein the sun-facing side of the one or more reflectors have a first focal region and a second focal region or a plurality of focal regions.

27. The solar PV system of claim 26, wherein the first focal region and the second focus or the plurality of foci have parallel axes in a linear focus reflector system, and the other foci are closer to the reflector than the first focus is.

28. The solar PV system of claim 26, wherein one of the rotating members with the PV cells or cell assemblies is disposed at or near the first focus or at or near other foci or at or near each of the plurality of foci.

29. The solar PV system of claim 26, wherein a thermal energy collecting units is disposed at or near one focus and the one or more rotating members with the PV cells or cell assemblies are disposed at any position on the sun-facing side of the one or more reflectors, or located at or near the other foci.
